(19) United States
(12) Patent Application Publication
(10) Pub. No.: US 2014/0312893 A1
(43) Pub. Date: Oct. 23, 2014

(54) INTELLIGENT ELECTRONIC SENSORS FOR MONITORING ELECTRICAL CIRCUITS

(71) Applicants: DON BURKART, Long Beach, NY (US); AMIR MAKKI, Northfield, NJ (US)

(72) Inventors: DON BURKART, Long Beach, NY (US); AMIR MAKKI, Northfield, NJ (US)

(21) Appl. No.: 14/214,005

(22) Filed: Mar. 14, 2014

Related U.S. Application Data
(60) Provisional application No. 61/784,274, filed on Mar. 14, 2013.

(51) Int. Cl. G01R 31/28; G01R 33/07

(52) U.S. Cl. CPC G01R 31/28; G01R 33/07
USPC 324/251; 324/537

(57) ABSTRACT

Intelligent electronic sensors, system containing such sensors, and methods for using such sensors for monitoring electrical circuits are described herein. The electronic sensors can monitor current flow through a conducting line and are oriented substantially parallel to the conducting line. The electronic sensors comprise a sensor module comprising a current sensor chip, a shield, a conductor stabilizer located proximate the conducting line, and a securement device to connect the electronic sensor to the conducting line. These sensors may be non-intrusive, intelligent, multipurpose, have both a standalone and open architecture, and may be submersible. The sensors may be quickly mounted to live conducting lines without requiring outages and disturbing control circuitry and their outputs may be easily marshaled to new or existing IEDs. Other embodiments are described.

### PRIORITY

This application claims priority to U.S. Provisional Patent Application No. 61/784,274, filed on Mar. 14, 2013, the entire disclosure of which is hereby incorporated by reference.

### FIELD

This application relates generally to sensors and methods for using sensors. More particularly, this application relates to intelligent electronic sensors, systems containing such sensors, and methods for using such sensors for monitoring electrical circuits.

### BACKGROUND

On Aug. 14, 2003, just after 4 p.m. Eastern Daylight Time (EDT), the North American power grid experienced its largest blackout ever. The blackout affected an estimated 50 million people and more than 70,000 megawatts (MW) of electrical load in parts of Ohio, Michigan, New York, Pennsylvania, New Jersey, Connecticut, Massachusetts, Vermont, and the Canadian provinces of Ontario and Québec. Although power was successfully restored to most customers within hours, some areas in the United States did not have power for two days and parts of Ontario experienced rotating blackouts for up to two weeks. The North American Electric Reliability Council (NERC) has developed and implemented a standing procedure for investigating future blackouts and system disturbances. The standing procedure requires that all utilities monitor all tripping relay, circuit breaker, and teleprotection facilities that are classified as Bulk Electric Systems. The standing procedure is required under NERC Reliability Standard PRC-002 Disturbance Monitoring Equipment (DME).

Modern digital protection and monitoring devices (called Intelligent Electronic Devices or IEDs) provide compliance with NERC DME standards but upgrading legacy infrastructure with such IEDs is costly and time insensitive. Legacy systems are analog based and do not provide sufficient data for detailed analysis which limits the ability to determine root causes and mitigate risks of pending or actual failures. Most of the U.S. power grid including nuclear power plants is analog based but NERC demands digital information for fault analysis and diagnosis. Accordingly, the digitization (monitoring) of legacy infrastructure is a focal point for both utilities and manufacturers especially since the analog system is reliable, has useful life, and is by nature invulnerable to cyber attacks. Often the driver for replacement is compliance with NERC DME Standards.

The current practice is to monitor legacy equipment through the use of existing spare output contacts. In most cases, a limited quantity of output contacts are available and are primarily used for maintenance purposes such as tripping circuit breakers. In the rare event that spare output contacts do exist, a wire is connected from the output contact and marshaled to an existing or new IED. When spare contacts are not available, auxiliary devices with the needed output contacts are inserted into the existing control circuitry. In either case, the control circuitry is being modified/disturbed which poses major challenges because of the risk of accidental actuation which may lead to an extensive loss of facility. The major challenges include but are not limited to scheduling outages to ensure that the control circuitry is initially 100% de-energized/isolated and finally fully tested for continuity to catch any potential wiring errors.

### SUMMARY

This application relates to intelligent electronic sensors (IES), systems containing such sensors, and methods for using such sensors for monitoring electrical circuits. Exemplary embodiments of IESs may include a sensor body configured to attach to a conductor wire, a sensor, a microcontroller located within the sensor body, an outer shield, and a securement device configured to attach the electronic sensor device to the conductor wire. The sensor may be a Hall effect sensor, and may be non-intrusive to the conductor wire. In some embodiments, the IES may also include a conductor stabilizer configured to hold the conductor wire adjacent to the sensor.

The IES may include a data output cable in electronic communication with the microcontroller. The data output cable may be configured to communicate with a digital protection and monitoring device (IED). The microcontroller may include logic to determine which data to report to the IED, when to report data to the IED, or both.

In some embodiments, one or more sensors may be configured to monitor one or more of voltage, current, temperature, or geographic position. Additionally, the IES may include a stand-alone architecture without permanent or automatic interfaces to external equipment, or an open architecture that can interface with other sensors or system IEDs through either wired or wireless connections. IESs may also be is connectable in series to two other electronic sensor devices to monitor secondary potential transformer inputs to a three phase system. Additionally, the IES may be robust, such that it may be submersible.

### BRIEF DESCRIPTION OF THE DRAWINGS

The following description can be better understood in light of Figures, in which:

FIG. 1 illustrates an perspective view of an exemplary intelligent electronic sensor for detecting anomalies in electricity characteristics in electric circuits;

FIG. 2 illustrates a side view of the exemplary sensor of FIG. 1;

FIG. 3 illustrates an exploded view of the exemplary sensor of FIG. 1;

FIG. 4 illustrates a cross-sectional view perpendicular to a central axis of the exemplary sensor of FIG. 1;

FIG. 5 illustrated a cross-sectional view along a plane coaxial with a central axis of the exemplary sensor of FIG. 1;

FIG. 6 illustrates a perspective view of other embodiments of an exemplary intelligent electronic sensor with an alternate sensor housing shape;

FIG. 7 illustrates an array of exemplary sensors arranged as components in a fault information system; and

FIG. 8 illustrates an array of exemplary sensors arranged as components in a loss of potential monitoring system on a three phase circuit.

Together with the following description, the Figures demonstrate and explain the principles of exemplary intelligent electronic sensors for electric circuits and associated methods of making and using them. In the Figures, the size and relative placement of components and regions of illustrated devices may be exaggerated or modified for clarity. The same reference numerals in different drawings represent the same element, and thus their descriptions may not be repeated. Some drawings may omit certain components not necessary for describing the illustrated embodiments, but which would be known to those of ordinary skill in the art to be present in and with electric circuit sensors.

### DETAILED DESCRIPTION

The following description supplies specific details in order to provide a thorough understanding. Nevertheless, the skilled artisan will understand that the described sensors and associated methods of making and using the sensors can be implemented and used without employing these specific details. Indeed, the sensors and associated methods can be placed into practice by modifying the described systems and methods and can be used in conjunction with any other apparatus and techniques conventionally used in the industry. For example, while the description below focuses on sensors used for monitoring electrical circuits, they could also be used to monitor or record electrical power systems, monitor and determine when a fuse has been blown, use as a smart meter for electrical customers (measure and send metering data back to centralized location), provide analog or digital signaling to protective or metering devices and/or allow fast and easy indication for various mass transit applications such as traffic light failure.

As the terms on, attached to, or coupled to are used herein, one object (e.g., a material, a layer, a substrate, etc.) can be on, attached to, or coupled to another object regardless of whether the one object is directly on, attached, or coupled to the other object or there are one or more intervening objects between the one object and the other object. Also, directions (e.g., above, below, top, bottom, side, up, down, under, over, upper, lower, horizontal, vertical, “x,” “y,” “z,” etc.), if provided, are relative and provided solely by way of example and for ease of illustration and discussion and not by way of limitation. In addition, where reference is made to a list of elements (e.g., elements a, b, c), such reference is intended to include any one of the listed elements by itself, any combination of less than all of the listed elements, and/or a combination of all of the listed elements.

In some embodiments, intelligent electronic sensors (IES) may perform several important functions in monitoring the state of electric circuits and providing data of the state of the electric circuits being monitored, including data to comply with NERC DME requirements.

IES devices may offer a novel solution which allows for acceptable monitoring of legacy, analog equipment. This may permit the legacy equipment to stay in place by providing the same monitoring capability featured in IEDs, without the need for expensive replacement of the legacy analog equipment. This result can be obtained by supplementing existing, reliable analog infrastructure with IESs and marshaling their contact outputs to existing or new IEDs. Embodiments of IESs disclosed herein may exhibit one or more advantageous characteristics that may facilitate IED monitoring of vintage analog infrastructures without the need for extensive and costly electrical outages, and may require minimal new equipment.

First, IESs may be non-intrusive. Accordingly, they can be installed on live wires without taking outages and are therefore deployable in a fraction of the time/cost as compared to typical IED replacement programs.

Second, IESs may include intelligent on-board programmable microprocessors or microcontrollers that allow the IES to independently decide to either refrain or act on incipient failures. Traditional IED systems, on the other hand, concentrate processing functions at a central controller level (the central controller being fed data from multiple non-intelligent sensors). Moving intelligence from the device to the sensor level may provide flexibility for numerous potential specialized applications for monitoring electrical power systems, some of which are described below.

Third, IESs may be multipurpose. In such embodiments, each sensor can be configured to monitor and act upon single or multiple parameters such as voltage, current, temperature, and/or geographic position. In some configurations, the sensors can be used to provide analog inputs to IEDs to monitor performance of major substation equipment such as circuit breakers, power transformers, and protective relay systems under power system fault and disturbance conditions in compliance with NERC DME standards.

Fourth, IESs can comprise standalone architecture, meaning that in such embodiments, the IESs may not require interfaces to specialized equipment such as IEDs. In such embodiments, IESs may be capable of reporting their decisions and data independently by connecting to a computer cloud using an internal communications device or antenna. For example, the IES may include capability to access Wi-Fi, cellular, 3G or 4G wireless data networks, radio, or any other suitable wireless communications network and/or protocol.

Fifth, some embodiments of IESs can comprise an open architecture, such that they can interface to existing IEDs. Providing interfaces at the sensor level to connect to existing IED infrastructure such as numerical relays, fault recorders, events recorders, remote terminal units, and station alarm panels may be highly advantageous in simplifying, speeding up, and reducing the cost of ongoing upgrades, replacement projects, and new installations.

Sixth, some embodiments of IESs may be submersible and/or weather resistant that will continue to operate properly even under extensive flooding conditions, extreme weather, and other adverse conditions such as those incurred during Super Storm Sandy.

And seventh, in some embodiments, IESs can be utilized to digitize analog quantities such as ac current and ac voltage to provide usable data to IEDs and other data and event recording infrastructure.

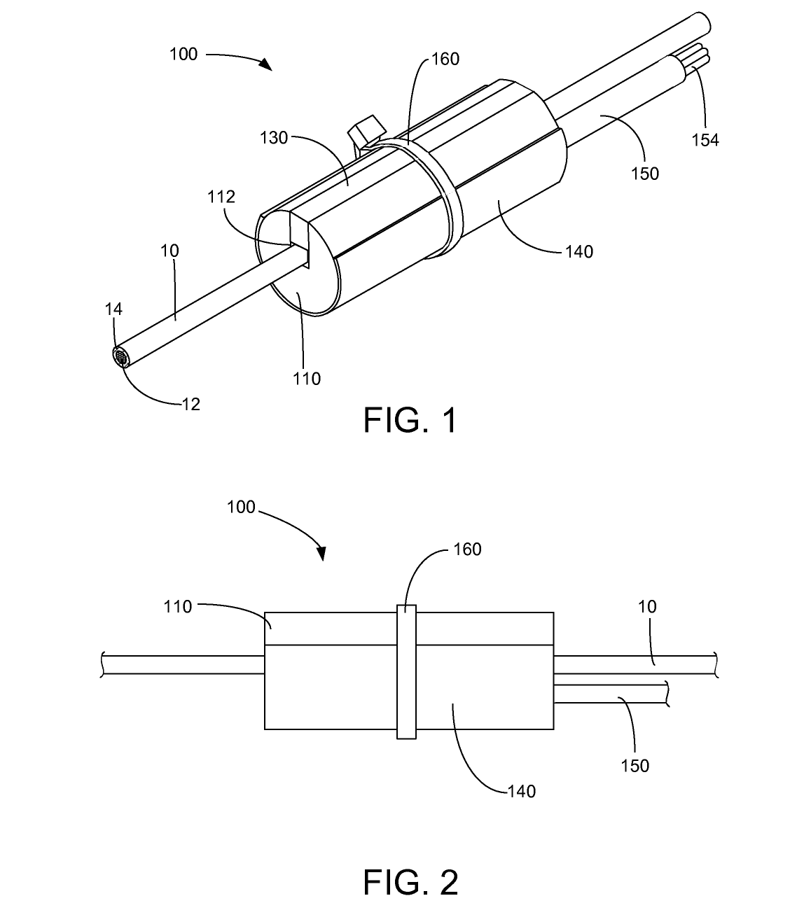

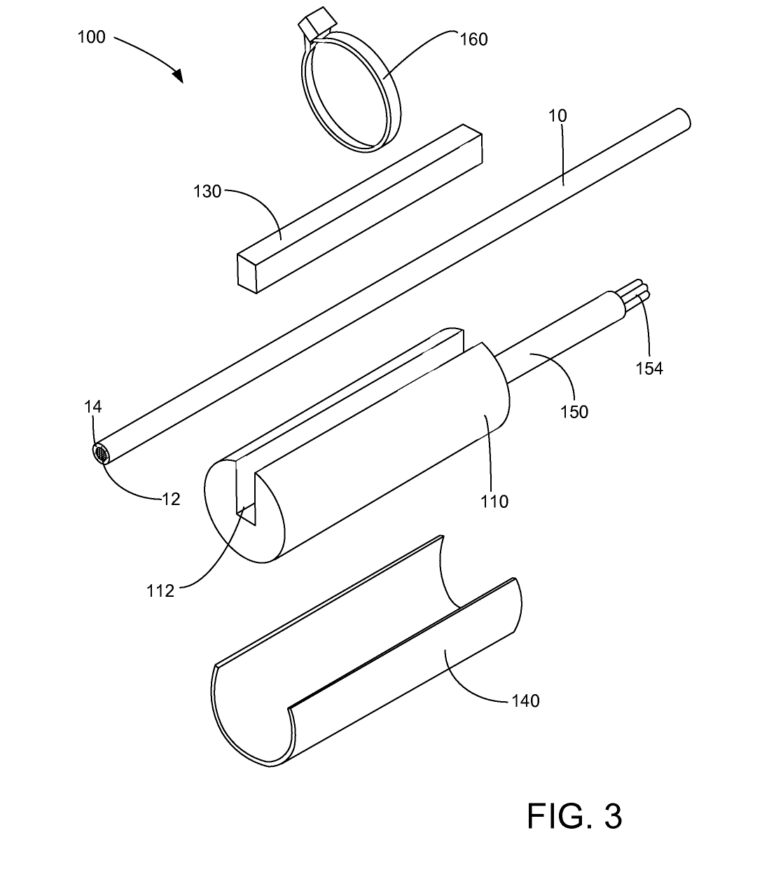

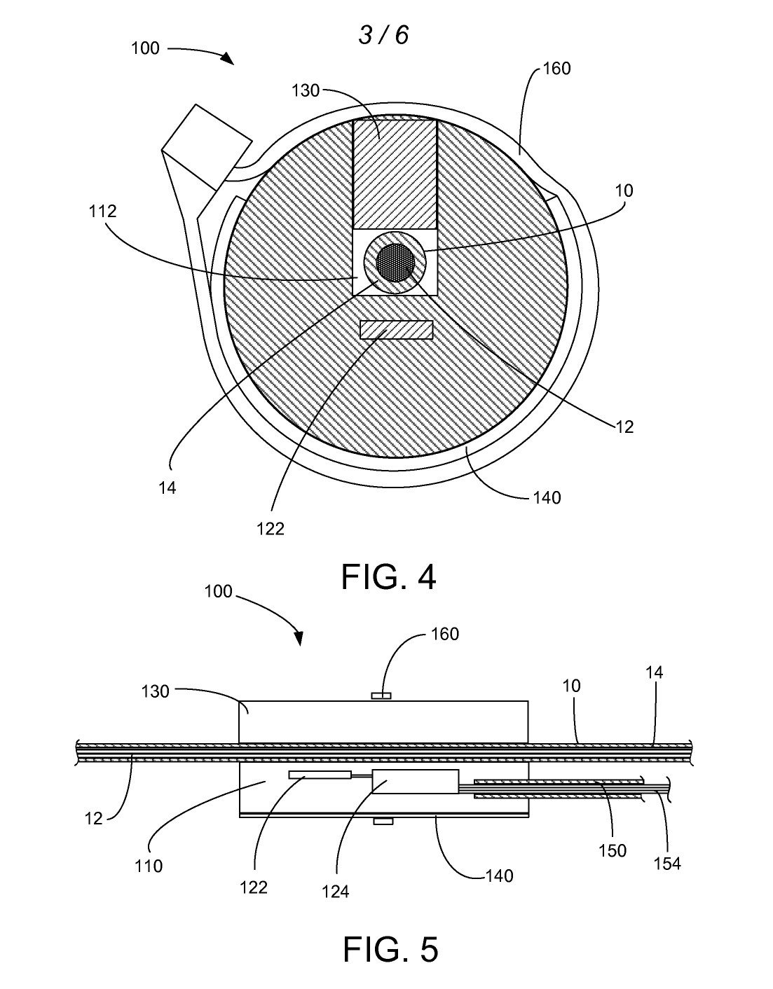

Some embodiments of IESs 100 having one or more of the features described above are shown in FIGS. 1-5. IES's 100 may monitor current flow through a conducting line 10 and may be placed externally on the conducting line 10 and oriented substantially parallel to the conducting line 10. As such, an IES 100 may be installed without compromising the insulation 12 or directly contacting the conductive element 14 of the conducting line 10. An IES 100 may include a sensor housing 110, a sensor 122, a conductor stabilizer 130, a shield 140, a data cable 150, and a securement device 160.

The sensor housing 110 may be formed from a non-conductive, weather resistant material such as plastic, epoxy, or any other suitable material. The sensor housing 112 may be formed in a generally cylindrical shape with a conductor slot 112 to accommodate conducting line 10 to be positioned generally coaxially within the cylindrical shape of the sensor housing 110. The sensor housing 110 may be formed with the sensor 122, a microcontroller 124, and a portion of data cable 150 embedded within the sensor housing 110 to protect the electronic components from weather or environmental damage. The sensor housing 110 may be formed in different sizes with different sizes of conductor slots 112 to accommodate various sizes of conducting lines 10 to be monitored. For example, the sensor housing 110 and the conductor slot 112 may sized to appropriately accommodate a 16 gauge DC conducting lines. Another embodiment may be sized to accommodate a large gauge AC high voltage conducting line 10. Other embodiments may be manufactured to accommodate any other size of conducting line 10 in need of monitoring.

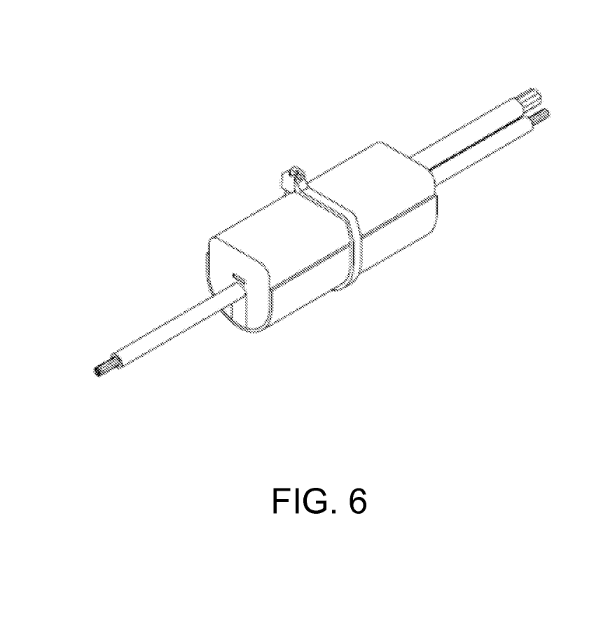

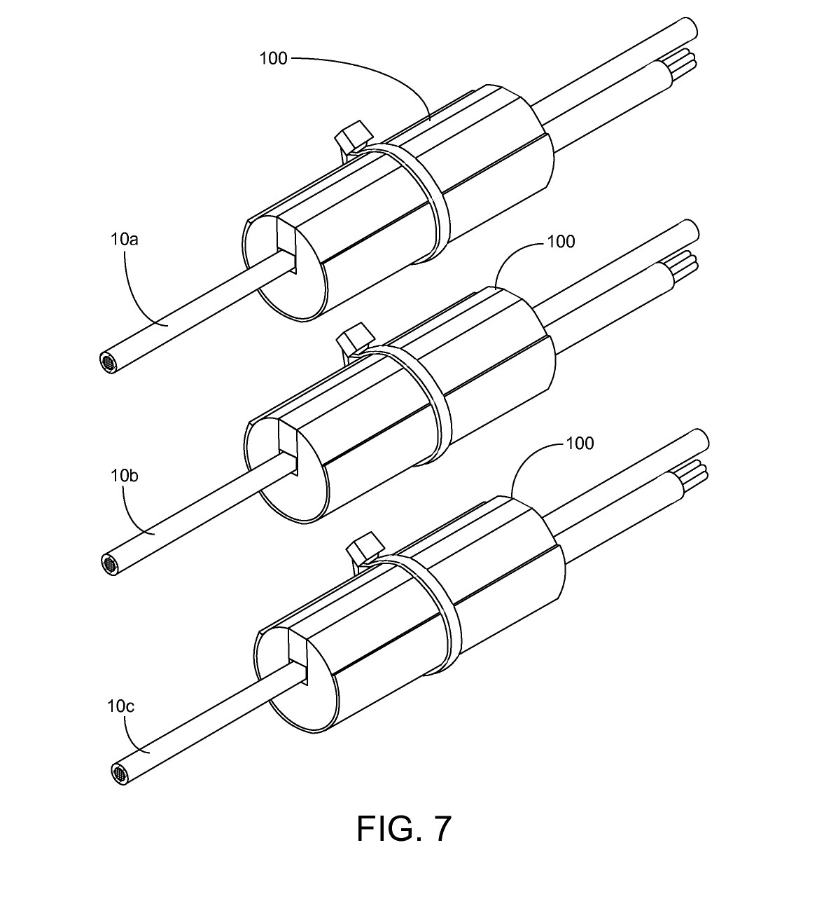

In other embodiments, the sensor housing may have shapes other than the cylindrical shape depicted in FIG. 1. One example of such a shape is shown in FIG. 6 where the sensor housing can contain one flat edge. In fact, the sensor housing may have any shape, including containing grooves or lines. In some embodiments, the sensor housing can have a shape (like that in FIG. 6) that is used to properly align and install the sensor in the desired location.

The sensor 122 may be a Hall-effect sensor, or any other type of sensor capable of non-contact monitoring of current in the conducting line 10. The IES may also include a microcontroller 124 to evaluate input from the sensor 122. The microcontroller 124 may be programmable for different monitoring applications. The microcontroller 124 may be a microprocessor, a programmable logic controller, a programmable logic device, or any other suitable device to process and evaluate data from the sensor 122 as described herein. Additionally, the microcontroller 124 may include memory or other components to achieve the functionality as described herein. For example, the IES 100 may be include additional sensors, such as accelerometers to provide indication of a downed wire, temperature sensors, or other desired sensors, depending on the desired application. Some sensors that may be desirable for use with the IES 100 are described in U.S. Pat. Nos. 7,746,055, 8,193,803, and 8203328, the disclosures of which are hereby incorporated by reference in their entirety.

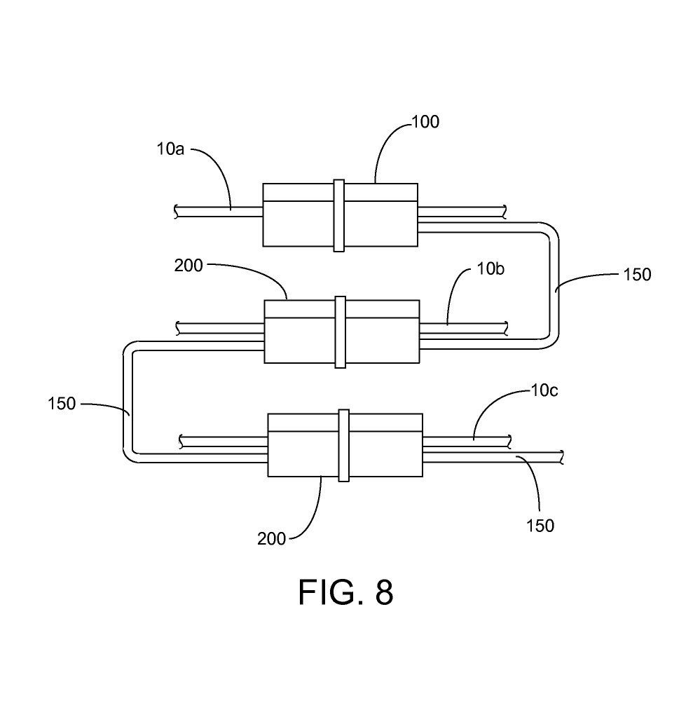

Similarly, the microcontroller may also include a radio or other wireless antenna, and a wire connection to provide connectivity to an IED or other data collection or processing infrastructure through data wire 150. The data wire 150 may include several different conductors for transmitting data to an IED. In some embodiments, such as is shown in FIG. 7, which is described in more detail below an IES 200 may include any or all of the features of the IES 100, along with a second data wire 150 to provide serial linking of IESs 100, 200 for communication between various IESs 100, 200 in different applications. In other embodiments, embodiments of an IES 300 (FIG. 8) may also include one or more LEDs to provide a visual status of the IES 300.

The conductor stabilizer 130 may be provided to fit into the conductor slot 112 or the sensor body 110 to securely attach the IES 100 to the conducting line 10 when properly installed. The conductor stabilizer 130 may be sized such that when the conducting line 10 is in the conductor slot 112 and the securement device 160 is applied, the securement device 160 presses the conductor stabilizer into the conductor slot 112 such that the conductor stabilizer 130 squeezes the conducting line 10 between the bottom of the conductor slot 112 and the conductor stabilizer 130. The resulting compressive squeezing between the sensor body 110, the conductor stabilizer 130, and the conducting line 10 may provide sufficient friction to hold IES 100 as a desired linear position on conducting line 10.

The shield 140 may be provided to reduce any interference with the sensor 122 from external influence of conductors other than conducting line 10, or from emf or other magnetic field influences from other devices that may give a false reading to the sensor 122. The shield 140 may be generally tubular in shape and closely covering an exterior portion of the generally cylindrical sensor body 110 with an opening for attachment of IES 100 to the conducting line 10. The shield 140 may be formed of a conductive metal or other suitable shielding material, such as carbon fiber. The shield 140 may be held in place around the sensor body with securement device 160. Securement device 160 may be one or more wire ties conventionally used in the industry for securing conductors to each other or to other devices.

Turning now to embodiments of the functionality of IESs, IESs may collect live data in a non-intrusive manner, which may substantially enhance the capability to detect and respond to anomalies on the grid. The IESs 100, may thereby bring legacy infrastructure up to information protocol standards demanded by NERC without upgrading the legacy infrastructure itself.

In some embodiments, the IESs can considerably reduce time and cost of rollout and can be used for deployment in and beyond the substation environment. FIGS. 7 and 8 illustrate different applications of IESs 100, 200 in a functional environment.

FIG. 7 illustrates a system of IES devices 100 used to independently monitor secondary current transformer inputs to protective relay systems and control circuits and provide an alarm or data signal to an IED upon discovery of AC faults and/or DC targets. In this example, three different conducting lines 10a, 10b, 10c are being monitored. For example, when an IES 100 detects a fault or target in any of the conducting lines, the IES detecting the fault or target may operate a contact to indicate the duration and type of fault. The contact is designed to connect to existing or new IEDS to report the event, for example, to a sequence of event recorder, a remote terminal unit (RTU), or a station alarm panel.

Turning now to FIG. 8, IES devices 100, 200 may be placed in series to collaboratively monitor secondary potential transformer inputs to three phase protective systems, shown as conducting lines 10a, 10b, and 10c in FIG. 8. The IESs 100, 200 may alarm upon occurrences of low or loss of potential conditions in one or more of the phases, which may lead to relay misoperations if left uncorrected. When a low potential condition is detected at one or more phases, the sensors may operate a contact for the duration of the condition and provide an indication of the faulted phases. In some embodiments, this may be done visually using a panel mount monitor equipped with three lights designated A, B, and C, corresponding to the three phases. The contact may also be designed to connect to existing or new IEDS.

With respect to the use of any plural and/or singular terms herein, those having skill in the art can translate from the plural to the singular and/or from the singular to the plural as is appropriate to the context and/or application. The various singular/plural permutations may be expressly set forth herein for sake of clarity.

In addition to any previously indicated modification, numerous other variations and alternative arrangements may be devised by those skilled in the art without departing from the spirit and scope of this description, and appended claims are intended to cover such modifications and arrangements. Thus, while the information has been described above with particularity and detail in connection with what is presently deemed to be the most practical and preferred aspects, it will be apparent to those of ordinary skill in the art that numerous modifications, including, but not limited to, form, function, manner of operation and use may be made without departing from the principles and concepts set forth herein. Also, as used herein, the examples and embodiments, in all respects, are meant to be illustrative only and should not be construed to be limiting in any manner.

1. An electronic sensor device for monitoring electrical circuits, the electronic sensor device comprising:
a sensor body configured to attach to a conductor wire;
a sensor;
a microcontroller located within the sensor body;
an outer shield; and
a securement device configured to attach the electronic sensor device to the conductor wire.

2. The electronic sensor device of claim 1, wherein the sensor is a Hall effect sensor.

3. The electronic sensor device of claim 1, wherein the electronic sensor device is non-intrusive to the conductor wire.

4. The electronic sensor device of claim 1, further comprising a conductor stabilizer configured to hold the conductor wire adjacent to the sensor.

5. The electronic sensor device of claim 1, further comprising a data output cable in electronic communication with the microcontroller.

6. The electronic sensor device of claim 5, wherein the data output cable is configured to communicate with a digital protection and monitoring device (IED).

7. The electronic sensor of claim 6, wherein the microcontroller includes logic to determine which data to report to the IED.

8. The electronic sensor of claim 6, wherein the microcontroller includes logic to determine when to report data to the IED.

9. The electronic sensor device of claim 1, wherein the sensor is configured to monitor one or more of voltage, current, temperature, or geographic position.

10. The electronic sensor device of claim 9, further comprising a second sensor configured to monitor one or more of voltage, current, temperature, or geographic position.

11. The electronic sensor device of claim 1, wherein the electronic sensor device comprises a stand-alone architecture without permanent or automatic interfaces to external equipment.

12. The electronic sensor device of claim 1, wherein the microcontroller includes an open architecture that can interface to other sensors.

13. The electronic sensor device of claim 1, wherein the electronic sensor device is submersible and will continue to operate under flooding conditions.

14. The electronic sensor device of claim 1, wherein the electronic sensor device is connectable in series to two other electronic sensor devices to monitor secondary potential transformer inputs to a three phase system.

15. The electronic sensor device of claim 1, further comprising a wireless transmitter.

16. An electronic sensor device, comprising:
a sensor body configured to attach coaxially to an external surface of an insulator of a conductor wire;
a current sensor located within the sensor body;
a microcontroller in electric communication with the current sensor, the microcontroller being located within the sensor body; and
a securement device configured to hold the current sensor proximate to the conductor wire.

17. The electronic sensor device of claim 16, wherein the current sensor is a Hall effect sensor.

18. The electronic sensor device of claim 16, further comprising a data output cable in electronic communication with the microcontroller.

19. The electronic sensor device of claim 18, wherein the microcontroller is configured to communicate with a digital protection and monitoring device (IED).

20. The electronic sensor of claim 6, wherein the microcontroller communicates with the IED through a wireless connection.

21. The sensor device of claim 1, wherein the sensor body contains a housing with a shape configured to be used to properly align the sensor during installation.
